(19) United States
(12) Patent Application Publication
(10) Pub. No.: US 2007/0227882 A1
(43) Pub. Date: Oct. 4, 2007

(54) SPUTTER CHAMBER FOR COATING A SUBSTRATE

(76) Inventors: Roland Trassl, Giessen (DE); Michael Geisler, Wachtersbach (DE); Albert Kastner, Hanau (DE)

Correspondence Address: FISH & RICHARDSON P.C., PO BOX 1022, MINNEAPOLIS, MN, 55440-1022, US

(21) Appl. No.: 11/692,868

(22) Filed: Mar. 28, 2007

(30) Foreign Application Priority Data
Mar. 29, 2006 (EP) EP06006474

(51) Int. Cl. C23C 14/00

(52) U.S. Cl. 204/298.02

(57) ABSTRACT

The invention relates to a sputter chamber for coating substrates, in which the so-called “picture frame effect” is eliminated or at least largely reduced. The thickness of the coating at the margin of a substrate hereby no longer deviates significantly from the thickness of the coating in the center of the substrate. This is attained thereby that the negative effect of the process gas—or of several process gases—which is introduced into the sputter chamber is equalized by an additional inert or reactive gas. At the margins of the substrates to be coated and on the substrate side facing away from the cathode thus an additional gas stream is generated, which is directed counter to the process gas stream.

### TECHNICAL FIELD

The invention relates to a sputter chamber for coating a substrate.

### BACKGROUND

For coating large-area substrates, the substrate is most often moved past a coating source located in a coating chamber. During the movement the substrate is continuously coated.

In the coating installation several such sequentially placed coating chambers may be located in a coating installation. If the installation includes a feed-in as well as also feed-out means, a so-called inline installation is involved independently of the number of coating chambers. However, as a rule, in inline installations, one or several coating chambers, as well as optionally pumping chambers and lock chambers, are disposed successively, the coating chambers being connected with the chambers located in the proximity via transport or connection channels for gas.

The conductance occurring in the transport channels is most often low compared to the conductance of a coating chamber in the transverse direction.

In such a coating chamber the local partial pressures are affected by different factors. For one, the gas distribution is changed through the moving substrate. For another the coating taking place on the substrate surface develops a suction performance selective for the reactive gas, however a negligible suction performance for the inert gas. This acts back onto the target surface such that local process conditions change as a function of the position of the substrate. For another, losses experienced by the plasma in the proximity of an uninterrupted wall or a substrate surface close to the plasma are greater than at a substrate edge. The differing partial pressures of the gases and the differing plasma interactions cause a difference in the magnitude of the coating rate, which leads to a fluctuating layer thickness of the substrate to be coated.

Thus, in dynamic coating the local gas pressure is affected by the moving substrate, since it changes the effective pumping delivery rate and different gas streamings occur in the edge region of the substrate. This leads to the so-called “picture frame effect”, which is apparent by a strong deviation of the layer thickness at the edge of the substrate relative to the layer thickness at the substrate center.

A method for the control of the evaporation rate or the composition of the material to be evaporated during a coating process under vacuum, with potentiometric measuring electrodes being installed in the coating installation, is known (DE 196 09 970 A1). With these measuring electrodes the fraction of a gas in the vacuum chamber or in a feed line connected to the vacuum chambers is compared to a reference gas and the measured potential difference is conducted to a regulation unit. With this regulation unit a generator responsible for the power supply of the cathode is driven. Through this configuration it becomes possible to obtain a stable sputter process.

A method for coating substrates in inline installations, in which the coating parameters are adjusted due to the acquired position of the substrate, is also known (DE 10 2004 020 466 A1). This method is distinguished thereby that a model is developed based on the Monte Carlo method, whereby a mean dynamic coating rate is determined. By varying the coating parameters, such as gas flow or discharge power, this mean dynamic coating rate is kept constant in the installation.

A coating installation is furthermore known, in which a sufficiently high concentration of reactive gas permits a complete reaction of the layer to be formed (DE 102 16 671 A1). This is made possible thereby that reactive gas is introduced into the substrate space.

Further known is a sputter chamber for coating a substrate, which comprises a first gas inlet and in which at least one further gas inlet is provided approximately at the level of the substrate (EP 0 860 514 A2). A substrate transport through the sputter chamber does not take place herein. Rather, the substrate rests on a rotary disk, which encompasses the substrate from below and at the side faces. The reactive gas is always introduced above the substrate surface to be coated.

Lastly, a sputter system is also known, in which a reactive gas flow takes place outwardly from the center of a cathode along the surface of a target (US 2005/0011756 A1). Two cathodes are here provided with one target each, and at each of these targets runs a separate reactive gas stream.

### SUMMARY

The invention addresses the problem of providing a device for coating substrates with which uniform coating is possible.

The invention consequently relates to a sputter chamber for coating substrates, in which the so-called “picture frame effect” is eliminated or at least highly reduced. The thickness of the coating at the margin of a substrate thereby no longer deviates significantly from the thickness of the coating in the center of the substrate. This is attained thereby that the negative effect of the process gas, or of several process gases, which is introduced into the sputter chamber, is equalized by an additional inert or reactive gas. At the margins of the substrate to be coated and on the substrate side facing away from the cathode, an additional gas stream is generated which is directed counter to the process gas stream.

The advantage attained with the invention comprises in particular that the cathodes do not need to be operated far from the reactive range of the characteristic, i.e. a higher sputter rate results at lower power.

According to the invention underneath the substrate, centrally or also in the margin regions of the substrate, at least one gas inlet is disposed. Through this at least one gas inlet a gas stream is generated which counteracts the gas stream coming from the cathode space, such that in the margin regions of the substrate equalization of both gas streams occurs. Thereby a uniform coating of the substrate is attained.

### DESCRIPTION OF DRAWINGS

FIG. 1 is a cross section through a sputter chamber,

FIG. 2 is a section along A-A of the sputter chamber depicted in FIG. 1 in the lower segment of the installation,

FIG. 3 is a section along B-B through a subregion of the sputter chamber according to FIG. 1 or a top view onto FIG. 2,

FIG. 4 is a section through a variant of the lower region of the sputter chamber,

FIG. 5 is a section B-B through a subregion of the sputter chamber in a variant of the lower region or a top view onto FIG. 4,

FIG. 6 is a section through a sputter chamber with a double magnetron.

### DETAILED DESCRIPTION

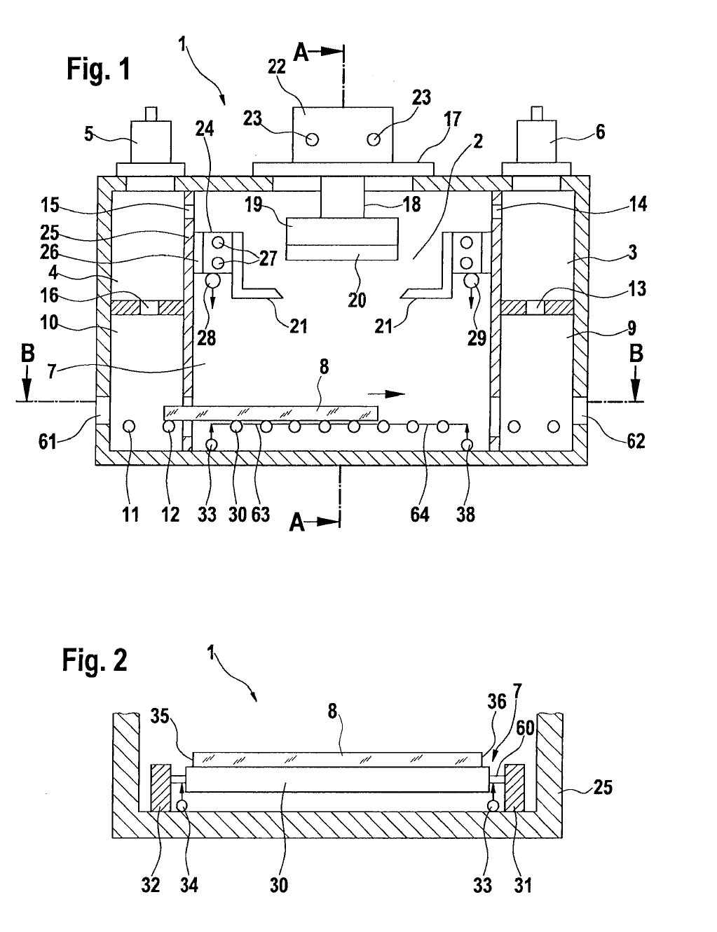

FIG. 1 shows a section through a sputter chamber 1 with a cathode space 2 and two adjacent pumping spaces 3,4 each equipped with a pump 5,6, preferably a turbopump. Beneath these pumping spaces 3,4 are disposed ancillary pumping chambers 9,10, between which is located a substrate space 7.

In the substrate space 7 a substrate 8 is transported on rollers 11, 12, 30 from left to right. The substrate 8 may be a glass sheet. The pumping spaces 3,4 are connected through openings 13 to 16 with the substrate space 7, the cathode space 2 or the ancillary pumping chambers 9,10.

On a cover 17 resting on the sputter chamber 1 via a mounting 18 is disposed a cathode 19, on which a target 20 is fastened. Opposite the cathode 19 is provided an anode 21 in the form of an aperture. On the cover 17 is disposed a cathode covering cap 22 containing a cooling system 23 in which preferably water flows as the coolant.

The anode 21 is connected with the wall 25 of the sputter chamber 1 through a mounting 24, between the mounting 24 and the wall 25 an insulation 26 being provided.

In the mounting 24 is contained a cooling system 27, in which water also flows as the coolant.

Beneath the mounting 24 are provided gas inlets 28, 29, through which a process gas and/or an inert gas, can be introduced. However, it is also possible to allow a process gas to stream into the cathode space 2 through one of the gas inlets 28, 29 and through the other a reactive gas, for example oxygen. Instead of introducing the gases separately into the cathode space 2, it is also feasible to premix the gases desired for the sputter process and to conduct this gas mixture via one these gas inlets 28, 29 to the cathode space 2. The gas inlets 28, 29 can also be disposed above the mounting 24. In this case, the process gas stream moves through the opening of the aperture 21 in the direction toward the substrate space 7. Opposite the gas inlets 28,29 and below the plane of the substrate 8 are located two further gas inlets 33,38. Their gas streaming is directed upwardly. Between the gas inlets 33 and 38 additional gas inlets may be provided. For example, in the center between the gas inlets 33, 38 a further gas inlet can be located.

As is evident in FIG. 1, the sputter chamber 1 is comprised of several compartments, namely the cathode space 2, the substrate space 7, the pumping spaces 3,4 and the ancillary pumping chambers 9,10. The complete glass coating installation is comprised of several series-connected sputter chambers 1, not shown transfer chambers and feed-in and feed-out means, in order to move the substrate from atmospheric pressure into the process vacuum and to atmospheric pressure again.

The sputter chamber 1 consequently involves a structured receptacle.

In the different compartments 2 to 4, 7, 9, 10 pressures of different magnitudes are obtained, wherein in the pumping spaces 3, 4 the lowest pressure is obtained and in the cathode space 2 the highest, since into the cathode space 2 gas is introduced through the gas inlets 28,29.

These different compartments 2 to 4, 7, 9, 10 in which different pressures are obtained, are separated by a conductance which is most often lower than the ten-fold of the effective volume flow rate which can be obtained through the pumps 5,6.

If the substrate 8 is moved through openings 61,62 from left to right into the substrate space 7, the effective pumping delivery rate of the pumps 5,6 changes. In the margin region of substrate 8 the gas streamings behave differently. In addition, the plasma-wall interaction changes in the substrate region. Through the different behavior of the gas streamings and plasma conditions the coating rate at the substrate margin increases or decreases. Since the different gas streamings occur in particular in the margin regions of substrate 8, this leads here to a nonuniform coating.

This nonuniform coating comes to carry weight especially in the case of very small substrates or specially formed substrates, which may lead to the substrate often having a different color at the margin region than in the center of the substrate.

Such nonuniform gas streamings are counteracted according to the invention in that beneath the substrate 8 or at the level of the substrate 8 at least one gas inlet 33,38 is provided in the proximity of the bottom of the sputter chamber 1. Through this gas inlet 33,38 process or reactive gas or a mixture of these two gas types can reach the substrate space 7 in order to equalize here the gas streamings occurring in the margin regions.

The gas inlets 33,38 are gas tubules with openings of approximately 0.8 mm, which are disposed at distances of approximately 10 cm. The gas tubules can lie transversely to the substrate direction of movement, i.e. parallel to cathode 19 above as well as also below the substrate plane. The gas tubules should be longer than the maximum width of the substrate 8, i.e. gas outlet openings are provided which are to the left and right outside of the substrate 8.

Between the transport rollers 11, 12, 30 cooled counter sputter metal sheets 63,64 are provided, which collect the material deposited in front or behind the passing substrate and consequently prevent the chamber walls beneath the rollers 11, 12, 30 from being coated. Suction cleaning of the region below the transport plane takes place via gap locks or transport openings to the adjacent ancillary pumping chambers 9,10. The counter sputter metal) sheets 63, 64 can also be extended to the right or left into the ancillary pumping chambers 9, 10.

The gas from the cathode space 2 streams counter to the gas, which flows from the gas inlets 33, 38 disposed beneath the substrate 8, as well to the plasma diffusing toward the substrate edge region.

The gas flowing from the gas inlets beneath the substrate 8 preferably reaches the margin regions of the substrate 8 at the same mass flow rate as the gas flowing from the cathode space 2. The gas flowing from beneath the substrate 8 is adjusted such that with respect to its effect on the layer formation, in particular on the deposition rate, it acts in the same manner as the substrate surface acting as a wall onto the plasma. As experiments have shown, through the gas inlet beneath the substrate 8 vortices at the edges of the substrate can be equalized. However, it is not completely clear how this equalization functions in detail. Gas streamings in a vacuum are not subject to the aerodynamics under atmospheric pressure. The gas particles in a vacuum stream in straight lines until they collide somewhere, for example with another gas particle or with a wall.

At a pressure of 1×10-3 mbar the particles have a mean free path length of approximately 7 to 8 cm. However, this length depends also on the atomic radius of the gas particles such that it is different for different gases.

A particle can reach the anode 21 or the chamber wall. Due to the interaction with the surface of anode 21 or chamber wall 25, the particle often adheres for a certain length of time—the so-called sticking effect—before it leaves the surface again. It can now move in any direction at any speed.

Due to the mean free path length there is no information exchange regarding speed and directions as is the gas for gas streamings under atmospheric pressure. Local fluctuations in the gas pressure are not equalized thereby that the particles collectively follow the pressure gradient. Rather the pressure equalization occurs via variations in the mean free path length and the number of collisions, such that in the final analysis the effect of the pump does become noticeable.

The gas inlets 33, 38 beneath the substrate 8 are individually or collectively adjustable and controllable. The gas flow of the gas inlets and its spatial-lateral distribution can be set to be a function of several parameters, for example of the target-substrate distance, of the electric power of the sputter cathode, of the form of the volumes beneath the substrate plane, of the chemical composition of the sputter target, of the chemical nature of the sputter gases employed, of the partial pressures of these gases or of the substrate thickness.

FIG. 2 shows a section of the sputter chamber depicted in FIG. 1 along A-A, with only a cut-out of the substrate space 7 being evident.

The substrate 8, disposed on a roller 30 is evident, with the roller 30 being connected via an axle 60 with supports 31,32. These supports 31,32 can, in turn, be connected with a driving system, or a be a part of a driving system, with which the roller is set into motion. Such a driving system is not shown in FIG. 2.

However, depicted are the two preferably opposing gas inlets 33, 34. From these gas inlets 33,34 a process or reactive gas or a mixture of the two gas types reaches the substrate space 7. This gas streams counter to the gas coming from the cathode space 2.

The gas inlets 33, 34 are located beneath the substrate 8 and extend beyond the margin region 35,36 of substrate 8 in order for the equalization of the gas streamings to occur here. In order for the equalization to occur in the margin regions 35,36 of the substrate 8, the velocities of the gases streaming counter to one another in these margin regions 35, 36 are of approximately the same magnitude.

This can be attained thereby that the pressure of the gas or of the described gas mixture can be precisely adjusted before it leaves the gas inlets 33,34.

The gas inlets 33, 34 have herein preferably a defined distance to the margin regions 35,36 of the substrate 8.

In the representation of FIG. 2 the substrate 8 moves into the plane of drawing. If the substrate 8 is glass, it moves at a rate of few meters per minute. The streaming velocity of the gas particles in comparison is higher by orders of magnitude, such that the moving substrate 8 does not generate any vortices which are comparable to vortices in the atmosphere. However, through the substrate movement the conductances in the vacuum chamber change slowly, which also affect the local distribution of the reactive gas fraction.

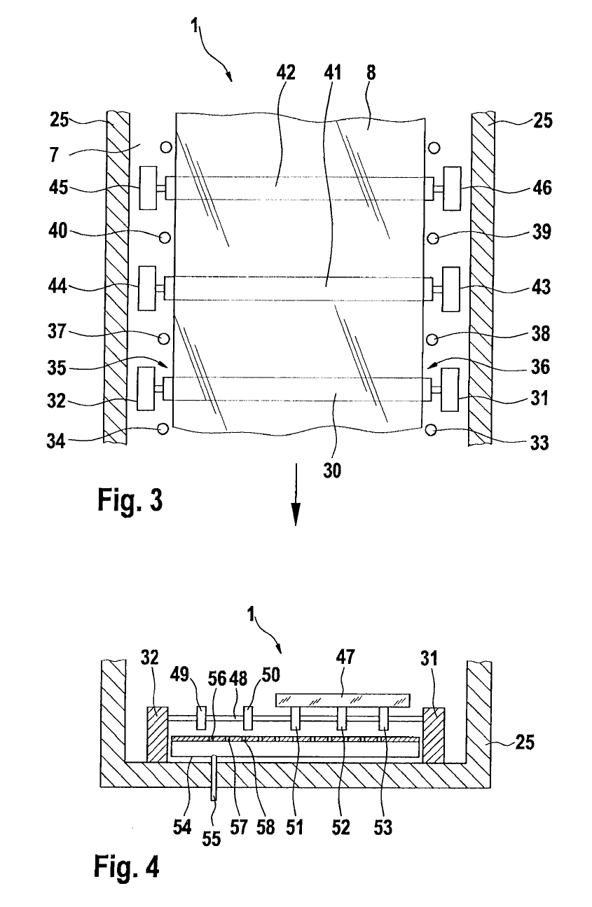

FIG. 3 shows a section along B-B through the sputter chamber 1 according to FIG. 1. FIG. 3 is thus a top view onto FIG. 2. The substrate 8 lies in the substrate space 7 on rollers 30, 41, 42, which, in turn, are connected with supports 31, 32, 43 to 46. Between these supports 31, 32, 43 to 46 in the margin region 35, 36 of substrate 8 are several gas inlets 33, 34, 37 to 40, from which gas streams in the direction of the margin regions 35, 36, in order to equalize the gas streamings coming from there.

Therewith, via these individually adjustable gas inlets 33, 34, 37 to 40, not only one gas but also several gases can be introduced simultaneously into the substrate space 7, for example an inert gas and a reactive gas or even an inert gas and several different reactive gases. The gases can already leave the gas inlets 33, 34, 37 to 40 as the appropriate gas mixtures with the desired composition.

The gases leaving the additional gas inlets 33, 34, 37 to 40 must effect a gas distribution, which is such that in the proximity of the margin regions 35,36 of substrate 8 local fluctuations of the partial pressures, which disturb the process, do not occur. This can be carried out by adjusting the gas flow, the gas or the gases being previously mixed in a distributor tube, connected upstream of the gas inlet tubes and not shown here.

FIG. 4 shows a section A-A through a variant of the lower region of the sputter chamber 1. The difference between it and the lower region shown in FIG. 2 comprises that the substrate 47, instead of on a transport roller 30, rests on several transport disks 49 to 53 connected with a shaft 48. In addition, instead of two individual gas inlets, one gas lance 54 is provided, which, in turn, is supplied by a gas inlet 55. The gas lance 54 comprises several nozzles 56 to 58, which may be provided for example at a distance of 10 cm. These nozzles are provided beyond the margin of substrate 47.

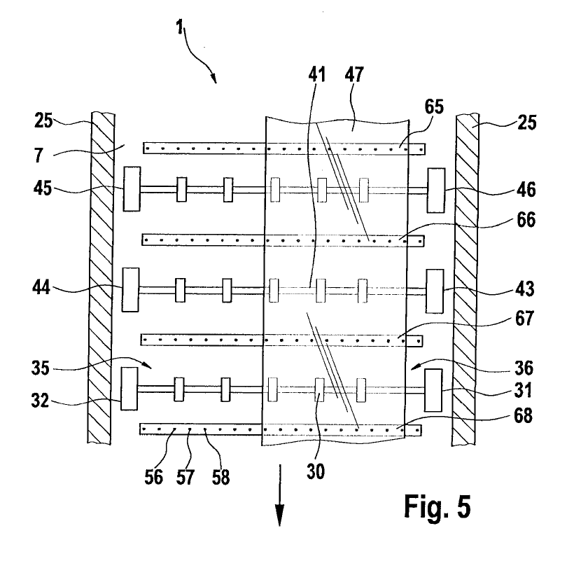

In FIG. 5 is depicted a section B-B in a variant of the lower region of the coating chamber. FIG. 5 is thus a top view onto FIG. 4.

Substrate 47 occupies herein only a portion of the width of the coating chamber. It can be seen that several gas lances 65 to 68 are disposed in series. Instead of the four gas lances 65 to 68 shown here, more or fewer than four gas lances can be provided. The gas lances 65 to 68 have linearly disposed nozzles, of which only three are provided with reference numbers 56, 57, 58.

With the different variants of the gas inlet it is possible to adapt the coating conditions in different types of glass coating installations to the least irregularity of the layer thickness. This is also possible if the geometry of the installation is different from the one depicted in FIG. 1.

The layer thickness uniformity can moreover be adapted to substrates to be coated of any shape. Since the “picture frame effect” occurs at all margins of a sheet, shape of the glass sheet and its dimensions are of importance in so far as it is no longer sufficient to provide the additional gas inlets only in the margin region of the coating chamber but rather the gases must now be supplied according to FIG. 5 by means of several gas lances 65 to 68, which have gas outlet openings at regular distances over the approximately entire chamber width. In glass coating installations not only rectangular and large glass sheets are coated, as is shown in FIG. 1 to 3, but also sheets with markedly smaller dimensions, as indicated in FIG. 4 and 5. Sheets with special and irregular layout of shape are also coated, which, moreover, also rest arbitrarily and irregularly on transport rollers.

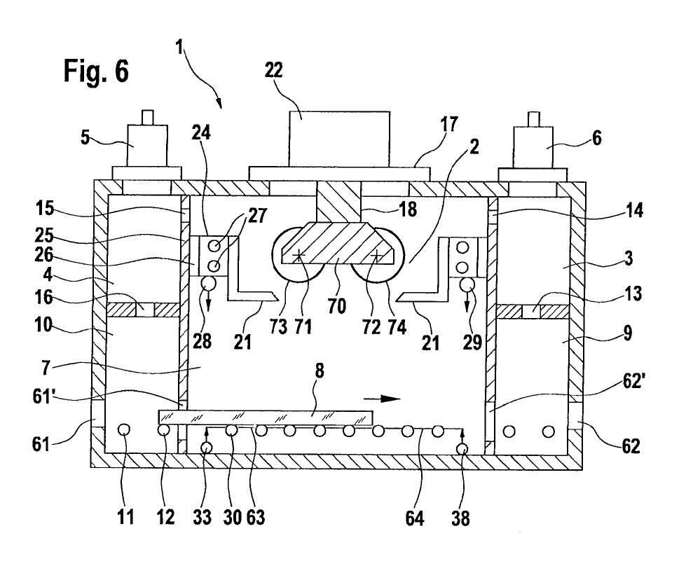

In FIG. 6 is depicted a sputter chamber 1 comprising two rotatable magnetrons 73, 74, which are rotatable about their longitudinal axis 71, 72 in a bearing block 70. In this case the anode 21 is not connected as anode, but rather acts only as an aperture which is connected to ground or is at a floating potential.

Particular implementations have been described. Other implementations are within the scope of the following claims.

What is claimed is:

1. A sputter chamber for coating a substrate, comprising:
a first gas inlet above the substrate which outputs a gas streaming in the direction toward the substrate; and
a second gas inlet which is provided approximately at or beneath the level of the substrate;
wherein the gas streamings of the first gas inlet and second gas inlet are directed counter to one another and are superimposed at the margins of the substrate to be coated.

2. The sputter chamber as claimed in claim 1, wherein the first gas inlet above the substrate and the second gas inlet have opposing gas outlet openings at the level of the substrate.

3. The sputter chamber as claimed in claim 1, wherein the second gas inlet is disposed beneath the substrate.

4. The sputter chamber as claimed in claim 1, wherein the second gas inlet is disposed in a margin region of the substrate.

5. The sputter chamber as claimed in claim 1, wherein the second gas inlet has a lateral distance from a margin region of the substrate.

6. The sputter chamber as claimed in claim 1, wherein the first gas inlet is disposed above the substrate and beneath a cathode of the sputter chamber.

7. The sputter chamber as claimed in claim 1, further comprising a cathode space, a substrate space, at least one pumping space and at least one vacuum space.

8. The sputter chamber as claimed in claim 7, wherein the cathode space is located between a cathode and an anode.

9. The sputter chamber as claimed in claim 8, wherein the anode is formed as an aperture through which sputtered target material reaches the substrate.

10. The sputter chamber as claimed in claim 9, wherein the first gas inlet is disposed above the substrate in the substrate space and behind the aperture.

11. The sputter chamber as claimed in claim 7, wherein the substrate space is provided between an anode and the substrate.

12. The sputter chamber as claimed in claim 7, wherein at both sides of the cathode space one pumping space each is provided.

13. The sputter chamber as claimed in claim 7, wherein at both sides of the substrate space one fore-vacuum space each is provided.

14. The sputter chamber as claimed in claim 7, wherein the pumping space is fluidly connected with the cathode space and the fore-vacuum space.

15. The sputter chamber as claimed in claim 1, characterized in that the first gas inlet is disposed above the substrate in a substrate space and behind an aperture through which sputtered target material reaches the substrate.

16. The sputter chamber as claimed in claim 1, wherein the second gas inlet is a gas lance with a plurality of nozzles.

17. The sputter chamber as claimed in claim 1, wherein the first gas inlet is disposed above the substrate.

18. The sputter chamber as claimed in claim 1, wherein the first gas inlet is disposed beneath the substrate.
